(19) United States
(12) Patent Application Publication
(10) Pub. No.: US 2025/0264811 A1
(43) Pub. Date: Aug. 21, 2025

(54) EXPOSURE PROCESS DETERMINATION METHOD, EXPOSURE APPARATUS, EXPOSURE METHOD, ARTICLE MANUFACTURING METHOD, AND COMPUTER-READABLE STORAGE MEDIUM

(71) Applicant: CANON KABUSHIKI KAISHA, Tokyo (JP)

(72) Inventors: HIROMU SUGIYAMA, Tochigi (JP); NAOTO OKAWA, Tochigi (JP)

(21) Appl. No.: 19/052,880

(22) Filed: Feb. 13, 2025

(30) Foreign Application Priority Data
Feb. 21, 2024 (JP) 2024-024609

(51) Int. Cl. G03F 7/00

(52) U.S. Cl. CPC G03F 7/70608; G03F 7/70333; G03F 7/706837

(57) ABSTRACT

An exposure process determination method of projecting an image of a pattern of an original onto a substrate and exposing the substrate according to the present invention, includes: a flatness obtaining step of obtaining a flatness in an exposure region of the substrate; an evaluation value deriving step of deriving an evaluation value based on the flatness; and a determining step of determining whether to perform multifocal exposure in which exposure processing is performed a plurality of times at a plurality of focus positions on the exposure region of the substrate based on the evaluation value.

### BACKGROUND OF THE INVENTION

### Field of the Invention

The present invention relates to a determining exposure process determination method, an exposure apparatus, an exposure method, an article manufacturing method, and a computer-readable storage medium.

### Description of the Related Art

Along with the diversification of products manufactured by an exposure apparatus, there has been a need for the exposure apparatus to support various substrates and various processes. One of them is an exposure processing on a SiC substrate, in which a substrate having a large diameter is used to improve productivity. However, when the diameter of the substrate is enlarged, the flatness in the substrate surface (maximum value of the difference in position in the height direction of the substrate) is increased.

Japanese Patent Application Laid-Open No. 2006-114526 discloses a technique of performing exposure according to a focus offset for each shot region determined based on flatness when a substrate having a large flatness is exposed by an exposure apparatus.

In the technique disclosed in Japanese Patent Application Laid-Open No. 2006-114526, the focal position is determined for each exposure region in the substrate in accordance with the flatness, and when the flatness is larger than the depth of focus, distortion occurs in the pattern shape to be transferred. Multifocal exposure (FLEX: Focus Latitude Enhancement Exposure) is known as a method for exposing a substrate having a flatness exceeding the depth of focus. The FLEX method is an exposure method in which exposure is performed a plurality of times at a plurality of different focal positions, and by applying the FLEX method to an exposure region whose flatness is larger than the depth of focus, distortion of a pattern shape to be transferred can be prevented.

However, since the multifocal exposure involves driving the focal position a plurality of times, the exposure processing time becomes longer, and a decrease in productivity is unavoidable.

### SUMMARY OF THE INVENTION

The present invention is to provide a method for determining exposure processing with high productivity in exposure processing of a substrate with large flatness.

An exposure process determination method of projecting an image of a pattern of an original onto a substrate and exposing the substrate according to the present invention, includes: a flatness obtaining step of obtaining a flatness in an exposure region of the substrate; an evaluation value deriving step of deriving an evaluation value based on the flatness; and a determining step of determining whether to perform multifocal exposure in which exposure processing is performed a plurality of times at a plurality of focus positions on the exposure region of the substrate based on the evaluation value.

Further features of the present invention will become apparent from the following description of exemplary embodiments with reference to the attached drawings.

### BRIEF DESCRIPTION OF THE DRAWINGS

FIG. 1 is a view showing an exposure apparatus according to an embodiment of the present invention.

FIG. 2 is a diagram illustrating a flatness measuring device according to the embodiment.

FIG. 3 is a flowchart for determining exposure processing according to the embodiment.

FIG. 4 is a flowchart for determining exposure processing according to the embodiment.

### DESCRIPTION OF THE EMBODIMENTS

Hereinafter, preferred embodiments of the present invention will be described with reference to the accompanying drawings. In the drawings, the same reference numerals denote the same components, and a repetitive description thereof will not be given.

Hereinafter, a direction perpendicular to the substrate mounting surface on which the substrate W is mounted on a substrate stage 115 (a direction parallel to an optical axis of a projection optical system 111) is defined as Z direction. In a plane perpendicular to the Z direction, directions perpendicular to each other are defined as X direction and Y direction. In addition, drawings described below may be drawn to scale different from actual scales in order to facilitate understanding of the present embodiments.

### EMBODIMENTS

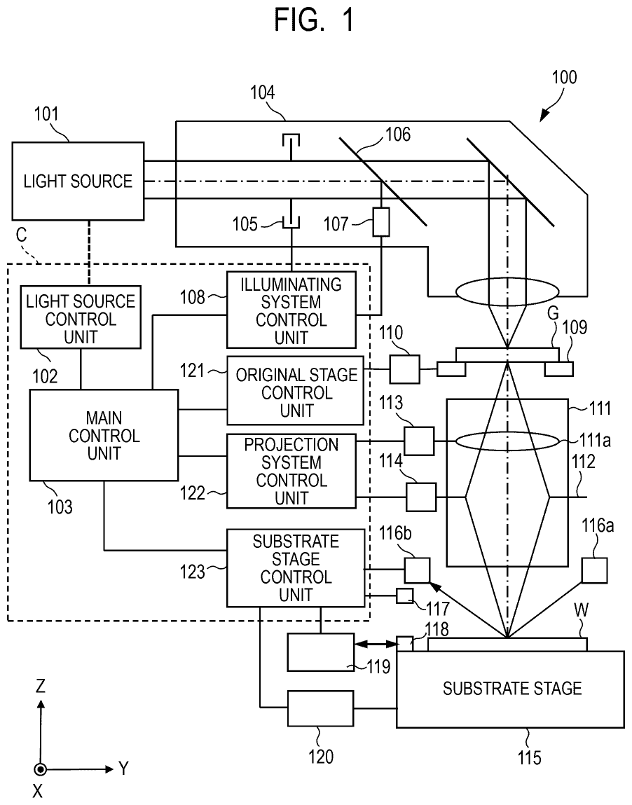

FIG. 1 is a schematic configuration diagram of an exposure apparatus 100 according to an embodiment of the present invention. The exposure apparatus 100 is a lithographic apparatus for forming a pattern on the substrate W.

The exposure apparatus 100 according to the present embodiment includes a light source 101, a control unit C, an illumination optical system 104, an original stage 109, a projection optical system 111, and a substrate stage 115.

In the exposure apparatus 100 according to the present embodiment, light from the light source 101 is used to project an image of the pattern on an original G onto a photoresist surface on the substrate W and expose the photoresist surface. The original G is movably held by the original stage 109, and is disposed between the illumination optical system 104 and the projection optical system 111, specifically, in the vicinity of a position of the object plane of the projection optical system 111. The substrate W is movably held by the substrate stage 115, and is disposed at a position of an image plane of the projection optical system 111.

The control unit C includes a light source control unit 102, a main control unit 103, an illumination system control unit 108, an original stage control unit 121, a projection system control unit 122, and a substrate stage control unit 123, and controls the entire exposure apparatus 100. The main control unit 103 includes a CPU and a storage device (not shown) such as a memory, and controls each unit of the exposure apparatus 100. Specifically, a process of projecting an image of a pattern on the original G onto the substrate W, that is, a process of scanning and exposing the substrate W is controlled.

The exposure apparatus 100 exposes the substrate W by projecting the image of the pattern formed on the original G onto each of a plurality of shot regions on the substrate W. The exposure light emitted from the light source 101 is shaped into a predetermined shape via a shaping optical system (not shown) of the illumination optical system 104. The shaped exposure light is further incident on an optical integrator (not shown), and a large number of secondary light sources for illuminating the original G with a uniform illuminance distribution are formed by the optical integrator.

On an optical path of the illumination optical system 104, a field stop 105 that defines an illumination region of the original G is provided, and a position and size of the opening of the field stop 105 are controlled by an illumination system control unit 108. The field stop 105 is also referred to as a masking blade. For example, the masking blade limits the illumination region to a rectangular shape, and is configured so that four sides thereof can independently move. Accordingly, an arbitrary region on the original G can be illuminated.

A half mirror 106 is disposed on the optical path of the exposure light emitted from the illumination optical system 104, and a part of the exposure light illuminating the original G is reflected by the half mirror 106 and taken out. A photosensor 107 is disposed on the optical path of the reflected light of the half mirror 106, and the photosensor 107 generates an output corresponding to the intensity (exposure energy amount) of the exposure light.

The output of the photosensor 107 is converted into the exposure energy amount per pulse by an integration circuit (not shown) that integrates each pulse emission of the light source 101, and is provided to the main control unit 103 via the illumination system control unit 108.

A pattern corresponding to a circuit pattern of a semiconductor element to be manufactured is formed on the original G, and the original G is illuminated by exposure light emitted from the illumination optical system 104.

The projection optical system 111 reduces and projects a part of the pattern region of the original G onto the substrate W coated with a photoresist at a predetermined reduction ratio β (for example, ¼). In this state, the original stage 109 and the substrate stage 115 are scanned in mutually opposite directions (Y: scanning direction) with respect to the exposure light at the same speed ratio as the reduction magnification β of the projection optical system 111.

As a result of the light source 101 repeating pulsed light emission, an entire pattern region of the original G is transferred to a shot region (the shot region includes one or a plurality of chip regions) on the substrate W.

The original stage 109 is configured to hold the original G. The original stage 109 is provided with a movable mirror, and a position or displacement of the movable mirror is measured by a laser interferometer 110. As a result, the positions of the original stage 109 in the X direction and the Y direction are detected.

The original stage control unit 121 controlled by the main control unit 103 controls the position of the original stage 109 by controlling a driving mechanism (not shown) based on the position of the original stage 109 detected using the laser interferometer 110.

The projection optical system 111 has a movable optical element 111a. The movable optical element 111a is held by the lens barrel of the projection optical system 111, and is driven in an optical axis direction of the projection optical system 111 by a driving mechanism 113. The projection system control unit 122 is controlled by the main control unit 103. An aperture stop 112 is disposed on the pupil plane of the projection optical system 111. The diameter of an aperture of the aperture stop 112 can be controlled by a drive mechanism 114.

By adjusting a position of the movable optical element 111a in the optical axis direction of the projection optical system 111, it is possible to adjust the reduction magnification β and/or distortion of the projection optical system 111.

The drive mechanism 114 is configured to drive the movable optical element 111a by, for example, air pressure or a piezoelectric element.

The substrate stage 115 is configured to hold the substrate W, and can move in the optical axis direction (Z direction) of the projection optical system 111 and in a plane (XY plane) orthogonal to the optical axis direction by being driven by a drive mechanism 120. In addition, the substrate stage 115 can also be driven in rotational directions about the Z axis, the X axis, and the Y axis.

A movable mirror 118 is provided on the substrate stage 115, and the position or displacement of the movable mirror 118 is measured by a laser interferometer 119. Thus, the positions of the substrate stage 115 in the X direction and the Y direction are detected.

The substrate stage control unit 123 controlled by the main control unit 103 controls the position of the substrate stage 115 in the XY plane by controlling the drive mechanism 120 based on the position of the substrate stage 115 detected using the laser interferometer 119.

The exposure apparatus 100 includes a projection system that projects detection light onto a mark on the substrate W and a light receiving system that receives reflected light from the mark, and includes an alignment measurement unit 117 that measures a position (alignment position) of the mark in the X direction and the Y direction. The alignment measurement unit 117 shown in FIG. 1 is configured as an off-axis detection system that detects marks on the substrate W without via the projection optical system 111, but is not limited thereto.

For example, the alignment measurement unit 117 may be configured as a TTL (through the lens) detection system that detects a mark on the substrate W via the projection optical system 111. A relative position between the original stage 109 and the substrate stage 115 can be determined by the alignment measurement unit 117.

The exposure apparatus 100 further includes a focus measurement unit. The focus measurement unit is a focal plane detection device, has a projection system 116a that projects detection light toward the surface of the substrate W, and a light receiving system 116b that receives the reflected light, and measures the position (surface position, surface height) of the substrate W in the Z-axis direction.

The projection system 116a in the focus measurement unit of the present embodiment can be configured to cause the detection light to be obliquely incident on the surface of the substrate W, and the light receiving system 116b can be configured to receive the detection light (reflected light) reflected by the surface of the substrate W. The projection system 116a and the light receiving system 116b are each arranged obliquely upward facing a mark whose position is measured by the alignment measurement unit 117.

In the exposure apparatus 100 of the present embodiment, the surface position of the shot region is measured by the focus measurement unit, and the height distribution information of the surface of the substrate W can be obtained based on the measurement value. The height distribution information can also be used in common for all shot regions to control the height of the substrate W during exposure of each shot region. For example, the height distribution information is referred to calculate an offset value of the height of the substrate W which is corrected at the time of exposure of each shot region in accordance with the detection error of the light receiving system 116b and the concavo-convex shape of the pattern formed in each shot region.

As an example, a representative offset value for correcting the height of the substrate W is obtained from the obtained height distribution information, and the height of the substrate W at the time of exposure of each shot region can be controlled by using the representative offset value in common for all shot regions. In exposure apparatus 100, an exposure process, which will be described later, can be determined based on the acquired data of the position (height) in the Z direction with respect to the position in the X direction and the Y direction on the substrate.

The substrate stage 115 can be adjusted by the substrate stage control mechanism 129 by issuing a command from the substrate stage control unit 123 to set the substrate stage 115 at a desired position in the XY direction designated by the main control unit 103. The substrate stage control mechanism 129 adjusts the substrate stage 115 to a position in the Z direction designated by the main control unit 103 so that the substrate W can be exposed to light a plurality of times at different focal positions.

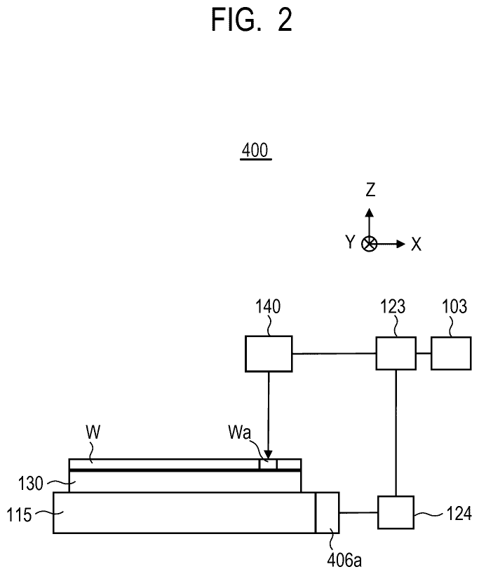

FIG. 2 shows a diagram of a measuring device 140 for collecting flatness data of the substrate W in the present embodiment. The measuring device 140 may be provided as a device external to the exposure apparatus 100 or may be provided in the exposure apparatus 100. The substrate W is held by a substrate holder 130 fixed to the substrate stage 115 movable in the X direction and the Y direction.

The main control unit 103 controls the substrate stage control unit 123 to move the substrate stage 115 to a plurality of coordinate positions set in advance by the drive mechanism 120, and measures the position (height) of the surface of the substrate W in the Z direction at each of the plurality of coordinate positions by the measuring device 140. The acquired measurement values of the positions in the Z direction at each of the coordinate positions (X and Y positions) in XY plane of the substrate W are stored in the control unit C as flatness data.

The obtained flatness data is divided for each exposure region according to the coordinate position of the exposure region in the substrate W, and is used as exposure region flatness data in each exposure region.

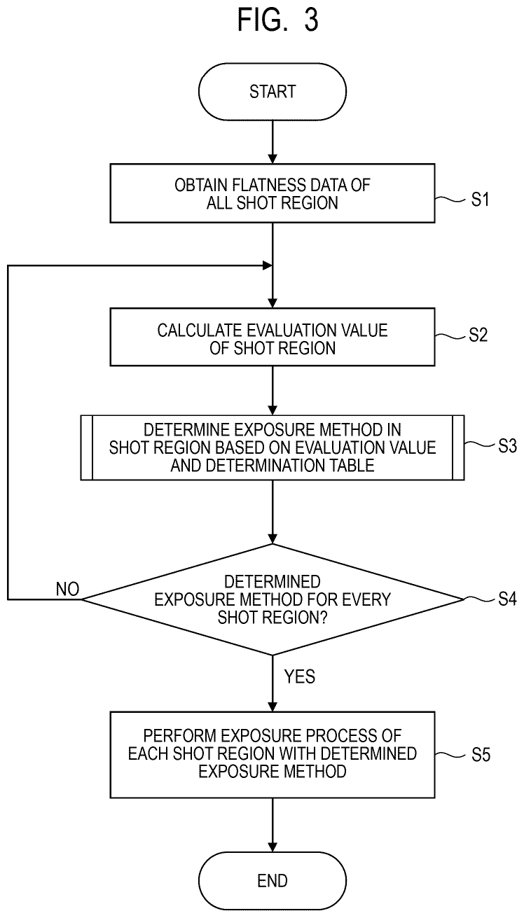

Hereinafter, a method of determining exposure processing according to the present exemplary embodiment will be described with reference to a flowchart illustrated in FIG. 3. Each step of the flowchart is performed by the control unit C, but is not limited to the control unit C. Each step of the flowchart may be performed by, for example, the main control unit 103 or may be performed by an information processing apparatus external to the exposure apparatus 100.

In step S1, flatness data at a plurality of predetermined positions in the XY plane is obtained for all shot regions of the substrate W (flatness obtaining step), and the process proceeds to step S2.

In step S2, a plurality of evaluation values is calculated based on the obtained flatness data. In the present embodiment, a first evaluation value R and a second evaluation value P are derived (evaluation value deriving step).

The first evaluation value R is an evaluation value obtained based on (an absolute value of) a difference value between a maximum value (a highest coordinate value in the Z direction) and a minimum value (a lowest coordinate value in the Z direction) of the flatness data in each shot region acquired. That is, the first evaluation value R is calculated by the following equation (1),

$$R = ( {S}_{m ax} - {S}_{m i n} ) / D \qquad ( 1 )$$

where Sₘₐₓ represents the maximum value of the flatness data in the shot region, Sₘᵢₙ represents the minimum value thereof, and D represents the depth of focus obtained based on the exposure conditions.

That is, the first evaluation value R is a value indicating how many times the depth of focus of the optical system the maximum height difference in the height distribution of the substrate surface in the shot region corresponds to.

The second evaluation value P is an evaluation value based on a value obtained from the flatness data in each divided region obtained by dividing the shot region into a plurality of regions. The shot region is divided into four quadrants from the center, the average value of the flatness data is first calculated for each quadrant with respect to the plurality of flatness data in the (vicinity of) center of each quadrant acquired in step S1, and a difference between the maximum value and the minimum value of the obtained four average values is acquired as the difference between the four quadrants.

Next, the second evaluation value P is calculated based on the obtained difference between the four quadrants and the depth of focus of the optical system. An average value Sᵢ of the flatness data in the central portion of the i-th quadrant in the shot region is represented by the following equation (2),

$${s}_{i} = \frac{1}{J} {\sum }_{j = 1}^{J} {s}_{ij} \\ ( i : 1 to 4 ) \qquad ( 2 )$$

where Sᵢⱼ(j: 1 to J) represents J pieces of flatness data in the central portion of the i-th quadrant (i: 1 to 4) of a shot region of interest.

Here, the second evaluation value P is expressed by the following equation (3),

$$P = ( {S}_{imax} - {S}_{imin} ) / D \qquad ( 3 )$$

where Sᵢₘₐₓ and Sᵢₘᵢₙ represent a maximum value and a minimum value in the four quadrants of the average value Sᵢ of the plurality of flatness data in the central portion of the i-th quadrant in the shot region, respectively.

The first evaluation value R is evaluated as a value of a ratio of the maximum height difference in the height distribution of the substrate surface in a certain shot region of interest to the depth of focus. On the other hand, the second evaluation value P is evaluated as a value of a ratio of the maximum value of the height difference of the substrate surface between the divided regions obtained by dividing the shot region into four to the depth of focus.

Here, although an example in which two evaluation values are used is shown in the present embodiment, the present invention is not limited to the first evaluation value R and the second evaluation value P described above. A plurality of flatness data in the exposure region may be used, and for example, flatness data at a specific position other than the central portion in the exposure region may be used as the evaluation value. The method of calculating the evaluation value may be any method as long as the relative relationship between the target flatness data and the depth of focus can be determined.

In the present embodiment, since the number of focus positions is used as a condition for performing multifocal exposure, the allowable value is set to the number of times the depth of focus.

In step S3 (determination step), exposure processing in the exposure region (shot region) is determined based on the obtained first evaluation value R and second evaluation value P and the determination table described in Table 1.

TABLE 1
Determination table for determining exposure method

| | P ≤ 1 | 1 < P |
|---|---|---|
| R ≤ 1 | Normal exposure | |

| | |
|---|---|
| 1 < R ≤ 2 | Multifocal exposure |

| | | |
|---|---|---|
| 2 < R ≤ 3 | Multifocal exposure | Divided exposure |

The exposure processing is determined as one of normal exposure in which exposure is performed once on the entire shot region, multifocal exposure in which exposure processing is performed by a plurality of exposures in which the focus is moved to a plurality of positions in the Z direction with respect to the entire shot region, and divided exposure in which the shot regions are divided into divisions and exposure processing is performed for each divided region obtained by dividing the shot regions.

In step S4, it is determined whether or not the determination of the exposure process has been performed on all the shot regions of the substrate W. When the determination of the exposure process for all the shot regions of the substrate W has not been completed, the process returns to step S2, and when the determination has been completed, the process proceeds to step S5.

In step S5, exposure processing of each shot region is performed by the exposure processing determined for each shot region of the substrate W.

Here, in the present embodiment, the exposure process is performed after the exposure process has been determined for all of the shot regions of the substrate W, but the present invention is not limited thereto. Each time the exposure process for one shot region is determined, the execution of the determined exposure process for the shot region may be started.

When the determination result of all the shot regions in the substrate W is the divided exposure in step S3, the exposure process may be re-determined by repeating the process from step S1 for each of the divided exposure regions.

Based on the determination table shown in Table 1, it is possible to determine, based on the first evaluation value R and the second evaluation value P of the shot region which is the exposure region, which method of the normal exposure, the multifocal exposure, and the divided exposure is used to perform the exposure processing on the shot region.

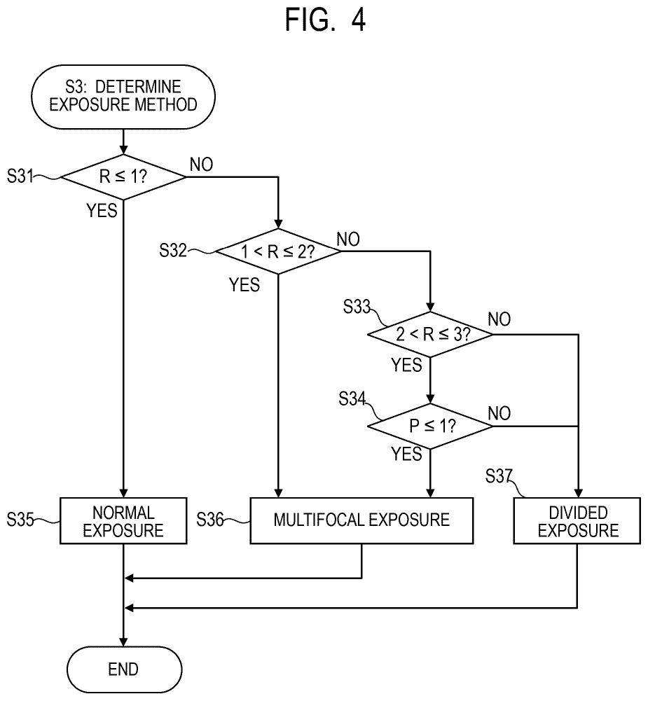

The determination of the exposure process in step S3 of the flowchart of FIG. 3 will be described with reference to the flowchart of FIG. 4.

In step S31, it is determined whether or not the first evaluation value R is equal to or less than 1. If it is equal to or less than 1, the process proceeds to step S35, and normal exposure is determined as exposure processing. If it is larger than 1, the process proceeds to step S32.

In the case where the first evaluation value R is 1 or less, since there are no two positions in which the height difference (difference in position in the Z direction) of the surface exceeds 1 in the substrate W, the second evaluation value P is also 1 or less. In this case, once an appropriate focus position is set, it is possible to execute exposure processing under an in-focus state for all positions (exposure positions) of the shot region.

In step S32, it is determined whether or not the first evaluation value R is greater than 1 and less than or equal to 2, and if it is satisfied, the process proceeds to step S36, and multifocal exposure is determined as exposure processing. When the condition is not satisfied, the process proceeds to step S33.

When the first evaluation value R is greater than 1 and less than or equal to 2, there are no arbitrary two positions in which the height difference (difference in position in the Z direction) of the surface exceeds twice the depth of focus in the shot region. Therefore, by performing two times of multifocal exposure in which the focal position is appropriately set on the shot region, it is possible to perform exposure processing with all portions in the shot region being within the depth of focus.

In step S33, it is determined whether or not the first evaluation value R is greater than 2 and less than or equal to 3, and when it is satisfied, the process proceeds to step S34, and when it is not satisfied, the process proceeds to step S37. When the first evaluation value R is greater than 2 and less than or equal to 3, two positions in the surface at which the maximum value of the height difference (difference in position in the Z direction) is greater than 2 times and less than or equal to 3 times the depth of focus are present in the shot region.

In step S34, it is determined whether or not the second evaluation value P is equal to or less than 1, and when it is satisfied, the process proceeds to step S36, and when it is not satisfied, the process proceeds to step S37. In step S34, when the second evaluation value P is equal to or less than 1, since the first evaluation value R is greater than 2 and equal to or less than 3, it can be determined that the variation in flatness between quadrants is smaller relative to the variation in flatness of the entire shot region.

Therefore, the four quadrants can be collectively determined to be capable of being subject to exposure under the same focus condition, and the exposure process can be performed on the shot region so that most of the shot region is within the depth of focus by two times of multifocal exposure in which the focal position is moved. Alternatively, an exposure process may be performed in which all the shot regions are within the depth of focus in three times of multifocal exposure in which the focal position is moved.

In step S37, divided exposure processing for exposing each quadrant is determined as exposure processing. In the divided exposure processing, one exposure processing is performed on each divided region (each quadrant). Alternatively, each divided exposure region (each quadrant) may be set as a shot region to be provided for the process of step S1 shown in FIG. 3, and the process from step S1 may be executed to determine the exposure process anew.

When it is determined in step S3 of FIG. 3 that multifocal exposure is to be performed, the number of times of multifocal exposure (the number of focus positions to be exposed) and the focus position in each multifocal exposure process are determined based on the flatness data of the exposure region.

Specifically, the number of times of multifocal exposure, that is, the number of focal positions to be exposed is determined based on the value of the first evaluation value R based on the flatness data acquired in step S2.

When the first evaluation value R is greater than 1 and less than or equal to 2, two times of multifocal exposure may be performed. The first focus position may be the minimum value of the flatness data (the surface position of the substrate W farthest from the original G), and the second focus position may be a position displaced toward the original G side by the depth of focus from the first focus position. Note that the first focus position is not limited to the position of the minimum value of the flatness data, and may be a position closer to the original G than the position and within the depth of focus.

When the first evaluation value R is greater than 2 and less than or equal to 3, the exposure can be performed under the condition that all the positions in the exposure region fall within the depth of focus at one time when the multifocal exposure is performed three times. The first focus position of the multifocal exposure is a position corresponding to the median of the maximum value and the minimum value of the flatness data.

The second focus position and the third focus position of the multifocal exposure are shifted from the first focus position by the depth of focus to the higher side and the lower side, respectively. By performing multifocal exposure at three focus positions as described above, all positions of the exposure region can be subjected to exposure processing within at least one focal depth.

When the first evaluation value R is greater than 2 and less than or equal to 3, it may be selected to perform two times of multifocal exposure. In particular, when the first evaluation value R is a value greater than 2 and less than or equal to 3 and close to 2, it may be selected to perform two times of multifocal exposure. Accordingly, most of the exposure area can be subjected to the exposure process in which the area is within the depth of focus while maintaining high throughput.

It is also possible to determine the focus position of the multifocal exposure without using the first evaluation value R and the second evaluation value P. The average value of the total flatness data of the exposure region may be set as the first focus position of the multifocal exposure, and the maximum value and the minimum value of the total flatness data may be set as the second focus position and the third focus position of the multifocal exposure.

Next, an example of a method of dividing an exposure region (shot region) into a plurality of regions when it is determined in step S3 of FIG. 3 that divided exposure in which exposure is performed by dividing the exposure region is performed will be described.

The exposure region is divided by a preset number of divisions based on the design of the pattern of the circuit formed on the original G and to be transferred. In the present embodiment, the number of divisions is set to four divided in quadrants, but a region obtained by integrating a plurality of adjacent regions may be divided based on the design of the pattern of the circuit to be transferred.

The focus position of each of the divided regions determined to be exposed by the divided exposure may be determined based on the flatness data or an evaluation value based on the flatness data. For example, the flatness value in each region (quadrant) used to calculate the second evaluation value P in step S2 may be determined as the focus position (exposure processing condition) of the divided region.

The flatness data of the substrate W used for calculating the first evaluation value R and the second evaluation value P can be acquired by the measuring device 140 of FIG. 2. As described above, the flatness data can also be acquired as the height distribution information of the surface of the substrate W by the focus measuring units (116a, 116b) of the exposure apparatus 100. The obtained flatness data of the substrate W can be further utilized as follows.

When the flatness data of the substrate W is collected by the exposure apparatus 100, the flatness data including the thickness of the photosensitive material in the substrate W is collected because the resist as the photosensitive material is coated on the surface of the substrate W. By acquiring in advance, the flatness data of the substrate W before applying the photosensitive material in the measuring device 140, it is possible to obtain data regarding the thickness of the applied photosensitive material by comparing the flatness data with the flatness data after applying the photosensitive material measured in the exposure apparatus 100. In consideration of the obtained data on the thickness of the photosensitive material, the first evaluation value R and/or the second evaluation value P in step S2 may be calculated and used.

### (Manufacturing Method of Article)

A method of manufacturing a semiconductor device as an article according to the present embodiment using the exposure apparatus described above includes a pre-process of forming an integrated circuit chip on a substrate W and a post-process of completing the integrated circuit chip on the substrate W formed by the pre-process as a product.

The article refers to, but is not limited to, a semiconductor IC element, a liquid crystal display element, and a MEMS. The article is manufactured by exposing a substrate W coated with a photosensitive agent using the above-described exposure apparatus, developing the substrate W, and processing the developed substrate W in another well-known process. Other well-known processes include etching, resist stripping, dicing, bonding, packaging, and the like. According to the method of manufacturing an article according to the present embodiment, an article can be manufactured with higher productivity than in the related art.

### (Program)

Embodiment(s) of the present invention can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2024-024609, filed Feb. 21, 2024, which is hereby incorporated by reference herein in its entirety.

What is claimed is:

1. An exposure process determination method of projecting an image of a pattern of an original onto a substrate and exposing the substrate, comprising:
a flatness obtaining step of obtaining a flatness in an exposure region of the substrate;
an evaluation value deriving step of deriving an evaluation value based on the flatness; and
a determining step of determining whether to perform multifocal exposure in which exposure processing is performed a plurality of times at a plurality of focus positions on the exposure region of the substrate based on the evaluation value.

2. The method according to claim 1, wherein the evaluation value deriving step includes a step of deriving the evaluation value based on a depth of focus of a projection optical system included in an exposure apparatus that performs the exposure process and data on the flatness.

3. The method according to claim 2, wherein the data on the flatness is a maximum value and a minimum value of the flatness in a shot region.

4. The method according to claim 2, wherein the data on the flatness includes a maximum value and a minimum value of the flatness of a plurality of regions obtained by dividing a shot region.

5. The method according to claim 4, wherein the data on the flatness includes a maximum value and a minimum value of the flatness of a central portion of each of the plurality of regions obtained by dividing the shot region.

6. The method according to claim 2, wherein the evaluation value includes a first evaluation value based on the depth of focus and a maximum value and a minimum value of the flatness in a shot region, and a second evaluation value based on the depth of focus and a maximum value and a minimum value of the flatness of a plurality of regions obtained by dividing the shot region.

7. The method according to claim 1, wherein an exposure condition of the multifocal exposure is set based on at least one of the flatness and the evaluation value.

8. The method according to claim 7, wherein the exposure condition includes a number of a plurality of focus positions different from each other in the multifocal exposure.

9. The method according to claim 7, wherein the exposure condition includes a plurality of focus positions different from each other in the multifocal exposure.

10. The method according to claim 1, wherein the determining step includes a step of determining, based on the evaluation value, one of an exposure processing in one exposure, the multifocal exposure, and a division exposure in which the exposure area is divided into a plurality of regions and exposure is performed for each of the plurality of regions.

11. The method according to claim 10, wherein a division in the exposure region when the division exposure is determined is performed based on a pattern formed on the original.

12. The method according to claim 10, wherein an exposure processing condition in each of divided regions obtained by dividing the exposure region when the division exposure is determined is set based on at least one of the flatness and the evaluation value.

13. The method according to claim 1, wherein the flatness is obtained by a measurement unit included in the exposure apparatus.

14. The method according to claim 1, wherein the flatness is obtained by a measuring device which is a device external to the exposure apparatus.

15. An exposure apparatus for exposing a substrate by projecting an image of a pattern of an original onto the substrate, comprising a controller configured to control an exposure processing to expose the substrate determined by an exposure process determination method
wherein the exposure process determination method comprises:
a flatness obtaining step of obtaining flatness in an exposure region of the substrate;
an evaluation value deriving step of deriving an evaluation value based on the flatness; and
a determining step of determining whether to perform multifocal exposure in which exposure processing is performed a plurality of times at a plurality of focus positions on the exposure region of the substrate based on the evaluation value.

16. An exposure method for exposing a substrate by projecting an image of a pattern of an original on the substrate, comprising:
a flatness obtaining step of obtaining flatness in an exposure region of the substrate;
an evaluation value deriving step of deriving an evaluation value based on the flatness;
a determining step of determining whether to perform multifocal exposure in which exposure processing is performed a plurality of times at a plurality of focus positions on the exposure region of the substrate based on the evaluation value; and
an exposing step of exposing the substrate by an exposure process determined based on the determination step.

17. An article manufacturing method, comprising:
exposing a substrate by an exposure process determined based on the method of claim 1; and
developing the exposed substrate.

18. A non-temporary computer-readable storage medium having stored thereon a program, for causing, when executed by a computer, the computer to execute the method of operation according to claim 1.
